(19) United States
(12) Patent Application Publication
(10) Pub. No.: US 2022/0200589 A1
(43) Pub. Date: Jun. 23, 2022

(54) SWITCH UNIT

(71) Applicant: Global Mixed-mode Technology Inc., Hsin-Chu (TW)

(72) Inventor: Chih-Chia Chen, Hsinchu County (TW)

(21) Appl. No.: 17/126,034

(22) Filed: Dec. 18, 2020

(51) Int. Cl. H03K 17/082; H03K 17/0812; H03K 17/693; H02H 3/18; H02H 9/02

(52) U.S. Cl. CPC H03K 17/0822; H03K 17/08122; H02H 9/02; H02H 3/18; H03K 17/693

(57) ABSTRACT

A switch unit is configured to provide reverse current protection. The switch unit comprises an input terminal, an output terminal, a switch device, an operational amplifier, and a voltage difference circuit. The switch device is coupled between the input terminal and the output terminal. The voltage difference circuit receives the voltage of the output terminal for generating a first signal, where the first signal is greater than the voltage of the output terminal. The operational amplifier is coupled to the input terminal and the first signal for generating a second signal to control the switch device.

### BACKGROUND OF THE INVENTION

### 1. Field of the Invention

The present invention relates to a switch unit, and more particularly, to a switch unit which is capable of providing reverse current protection.

### 2. Description of the Prior Art

In recent years with the development of the portable apparatus, the power management integrated circuit and the switch device have become indispensable to save the electric energy and prolong the usage time. In general, a switch device is a power channel component located between a power and a load. The system may determine whether or not to provide the power to the load by controlling the ON/OFF states of the switch device. In order to improve the reliability of the switch device, the designer may add a reverse current protection circuit to protect the peripheral devices surrounding the power.

FIG. 1 is a schematic diagram showing a conventional switch unit 10. The switch unit 10 comprises an input terminal Vi, an output terminal Vo, a switch device 100, a comparator 110, and a control circuit 120. When the voltage of the output terminal Vo is greater than the voltage of the input terminal Vi, the switch current Isw flows reversely from the output terminal Vo to the input terminal Vi. In order to prevent the generation of the reverse current, when the voltage of the output terminal Vo is greater than the voltage of the input terminal Vi, the comparator 110 enables the control signal Vc to have a low level via the control circuit 120, so as to turn off the switch device 100. Since the reverse current depends on the input offset voltage and the speed of the comparator 110, the switch unit 10 is unable to detect the accurate time point when the reverse current occurs, such that it tends to result that the reverse current is too large.

### SUMMARY OF THE INVENTION

According to the present invention, a switch unit which is capable of reducing a reverse current is provided. The switch unit comprises an input terminal, an output terminal, a switch device, an operational amplifier, and a voltage difference circuit. The switch device is coupled between the input terminal and the output terminal. The switch device has a switch current Isw, where the switch current Isw is the current flowing from the input terminal to the output terminal via the switch device. The input terminal may have a high voltage (e.g., 24 V) for an application of a high voltage circuit. The switch device may be an n-type power MOSFET. The drain of the n-type power MOSFET is coupled to the input terminal while the source of the n-type power MOSFET is coupled to the output terminal. The voltage difference circuit receives the voltage of the output terminal for generating a first signal, where the first voltage is greater than the voltage of the output terminal. According to one embodiment of the present invention, the difference value between the first signal and the voltage of the output terminal may be a predetermined value Vp, where the predetermined value Vp may be a relatively small value (e.g., about 20 mV). The operational amplifier comprises a non-inverted terminal coupled to the input terminal and an inverted terminal coupled to the first signal, so as to generate a second signal for controlling the ON/OFF states of the switch device.

When the switch unit is in a normal operation mode, the voltage of the input terminal is greater than the voltage of the output terminal. For speeding up the judgment of the reverse current, the prior art comparator is replaced by the operational amplifier according to one embodiment of the present invention. When the switch device is in a light-load mode, if the difference value between the voltage of the input terminal and the voltage of the output terminal is too small, the operational amplifier modulates the second signal for maintaining the difference value between the voltage of the input terminal and the voltage of the output terminal to be at least equal to the predetermined value Vp. At this moment the ON resistance of the switch device is equal to Vp/Isw. When the load of the switch device is lighter, the ON resistance of the switch device is larger. When the switch device is in a no-load mode, the switch device is turned off and there is no reverse current generated as a result. Therefore, through the combination of the operational amplifier and the voltage difference circuit, when the switch device is in the light-load mode, the switch unit may start a reverse current protection mechanism earlier for reducing the reverse current by modulating the ON resistance of the switch device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The above-mentioned and other objects, features, and advantages of the present invention will become apparent with reference to the following descriptions and accompanying drawings, wherein:

FIG. 1 is a schematic diagram showing a conventional switch unit; and

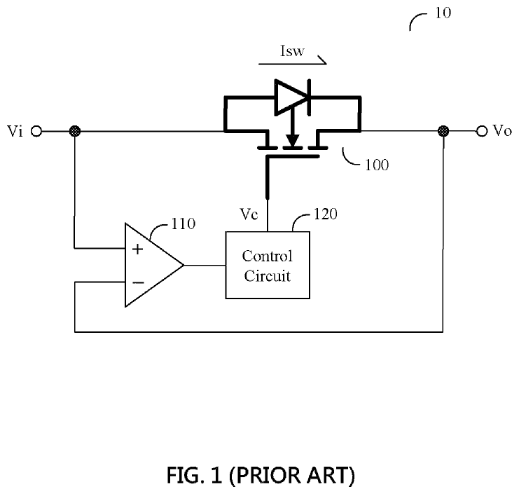

FIG. 2 is a schematic diagram showing a switch unit according to one embodiment of the present invention.

### DETAILED DESCRIPTION

Preferred embodiments according to the present invention will be described in detail with reference to the drawings.

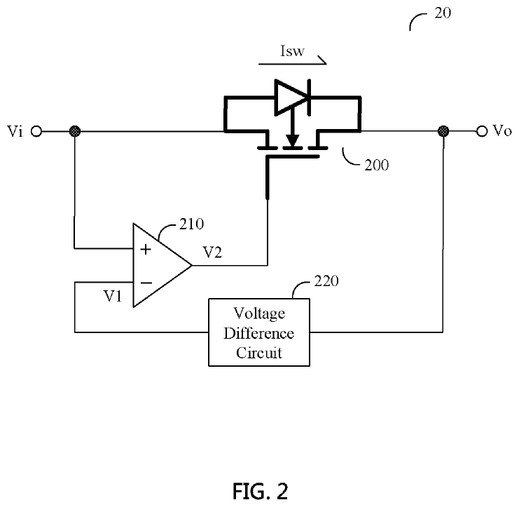

FIG. 2 is a schematic diagram showing a switch unit 20 according to one embodiment of the present invention. The switch unit 20 comprises an input terminal Vi, an output terminal Vo, a switch device 200, an operational amplifier 210, and a voltage difference circuit 220. The switch device 200 is coupled between the input terminal Vi and the output terminal Vo. The switch device 200 has a switch current Isw, where the switch current Isw is the current flowing from the input terminal Vi to the output terminal Vo via the switch device 200. The input terminal Vi may have a high voltage (e.g., 24 V) for an application of a high voltage circuit. As shown in FIG. 2, the switch device 200 may be an n-type power MOSFET. The drain of the n-type power MOSFET is coupled to the input terminal Vi while the source of the n-type power MOSFET is coupled to the output terminal Vo. The voltage difference circuit 220 receives the voltage of the output terminal Vo for generating a first signal V1, where the first voltage Vi is greater than the voltage of the output terminal Vo. According to one embodiment of the present invention, the difference value between the first signal V1 and the voltage of the output terminal Vo may be a predetermined value Vp, where the predetermined value Vp may be a relatively small value (e.g., about 20 mV). The operational amplifier 210 comprises a non-inverted terminal coupled to the input terminal Vi and an inverted terminal coupled to the first signal V1, so as to generate a second signal V2 for controlling the ON/OFF states of the switch device 200.

More specifically, when the switch unit 20 is in a normal operation mode, the voltage of the input terminal Vi is greater than the voltage of the output terminal Vo. For speeding up the judgment of the reverse current, the prior art comparator is replaced by the operational amplifier 210 according to one embodiment of the present invention. When the switch device 200 is in a light-load mode, if the difference value between the voltage of the input terminal Vi and the voltage of the output terminal Vo is too small, the operational amplifier 210 modulates the second signal V2 for maintaining the difference value between the voltage of the input terminal Vi and the voltage of the output terminal Vo to be at least equal to the predetermined value Vp. At this moment the ON resistance of the switch device 200 is equal to Vp/Isw. When the load of the switch device 200 is lighter, the ON resistance of the switch device 200 is larger. When the switch device 200 is in a no-load mode, the switch device 200 is turned off and there is no reverse current generated as a result. Therefore, through the combination of the operational amplifier 210 and the voltage difference circuit 220, when the switch device 200 is in the light-load mode, the switch unit 20 may start a reverse current protection mechanism earlier for reducing the reverse current by modulating the ON resistance of the switch device 200.

According to one embodiment of the present invention, when the switch device 200 is in the light-load mode, the switch unit 20 may start the reverse current protection mechanism earlier. When the switch device 200 is in the no-load mode, the switch device 200 is turned off and there is no reverse current generated as a result. Besides, the switch unit 20 may be applied to the high voltage circuit.

While the present invention has been described by the preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

Those skilled in the art will readily observe that numerous modifications and alterations of the device and method may be made while retaining the teachings of the invention. Accordingly, the above disclosure should be construed as limited only by the metes and bounds of the appended claims.

1. A switch unit comprising:
an input terminal;
an output terminal;
a switch device, coupled between the input terminal and the output terminal;
a voltage difference circuit; and
an operational amplifier, wherein the voltage difference circuit is coupled to the switch device for generating a first signal, the operational amplifier is coupled to the voltage difference circuit for generating a second signal to control the switch device, and the switch unit starts a reverse current protection mechanism by modulating an ON resistance of the switch device.

2. (canceled)

3. The switch unit of claim 1, wherein the switch unit is applied to a high voltage circuit.

4-5. (canceled)

6. The switch unit of claim 1, wherein the switch device is an n-type power MOSFET.

7. The switch unit of claim 6, wherein a drain of the n-type power MOSFET is coupled to the input terminal, and a source of the n-type power MOSFET is coupled to the output terminal.

8. The switch unit of claim 1, wherein a difference value between the first signal and a voltage of the output terminal is a predetermined value.

9. (canceled)

10. The switch unit of claim 8, wherein the predetermined value is about 20 mV.

11. The switch unit of claim 8, wherein when the switch device is in a light-load mode, if a difference value between a voltage of the input terminal and the voltage of the output terminal is too small, the operational amplifier modulates the second signal for maintaining the difference value between the voltage of the input terminal and the voltage of the output terminal to be at least equal to the predetermined value.
